(19) United States
(12) Patent Application Publication
(10) Pub. No.: US 2005/0243523 A1
(43) Pub. Date: Nov. 3, 2005

(54) Shock absorber means for components and cards

(76) Inventor: Bruno Coissac, Asnieres/Seine (FR)

Correspondence Address: Bruno Coissac, 258 Avenue D'Argenteuil, Asnieres Sur Seine, 92600, FR

(21) Appl. No.: 10/519,567

(22) PCT Filed: Jul. 3, 2003
(86) PCT No.: PCT/FR03/02066

§ 371 Date: Dec. 27, 2004

(30) Foreign Application Priority Data
Aug. 2, 2002 (FR) 02/09853

(51) Int. Cl. H05K 7/20

(52) U.S. Cl. 361/719

(57) ABSTRACT

The inventive shock absorber means for components and cards bearing printed circuits and components makes it possible to reduce the risk of microbreaks on printed circuit tracks and component failures. Said means comprises a flexible part (PS) arranged between the extremities thereof (EX). The inventive shock absorber means is used, in particular for the components and cards bearing printed circuit and components used for devices which are frequently moved and/or exposed to variable temperatures.

This invention concerns a shock-absorbing means of attachment for components and printed circuits and component support boards.

It may, depending on its mode of production, be used as a complement for or as a replacement for conventional means of attachment.

Printed circuit and component support boards are generally attached to the box which houses them by rigid means of attachment.

Such boards are thus subjected to any impacts and deformations which may be applied to these boxes.

Micro-breaks can be produced on the printed circuit tracks because the energy of an impact or of an expansion due to heat is transmitted to them.

If we place between the printed circuit support board and the box one or more means of attachment comprising a flexible part between their ends, the impacts and expansions to which the box is subjected are damped and largely absorbed before being transmitted to the printed circuit and component support board.

The shock-absorbing means of attachment or shock-absorbing complement for means of attachment according to this invention reduces the risks of breakdown for systems which have to be moved frequently and/or are subjected to thermal variations.

According to specific modes of production the means of attachment according to this invention can be produced entirely or partly in a flexible material of any shape comprising an opening at each end or at least at one of its ends.

It may comprise an external thread at each end or at least at one of its ends.

It may comprise a nut or an internal thread at each end or at least at one of its ends.

A simple mode of production may use a tab made of flexible material with two useful holes made in it.

The two useful holes may be held by fastening parts for one to an attachment ring on the printed circuit support board and for the other to the box housing the printed circuit support board.

This tab may also pass through an attachment ring on the printed circuit support board and be folded in such a way that its two useful holes are connected together to a screw or small column attached to the box housing the printed circuit support board.

In both cases, if there is sufficient room around the printed circuit support board, it is preferable to install the screws or small columns attached to the box in such a way as to form a perimeter greater than that of the printed circuit support board.

More sophisticated means of production may use a cylinder made of flexible material.

Each end of this cylinder can accommodate a screw of which the slotted head can be maintained by a small rod passing through the diameter of the cylinder or any other means, and by the shape of the cylinder which may comprise at each end an opening smaller than its internal diameter, the head of the screw being inserted forcibly and its thread oriented towards the outside.

A cylinder in flexible material open along its length and comprising at each end a ring or opening perpendicular to the open cylinder is also conceivable.

This open cylinder allows the handling, tightening and untightening of fastening parts passing through each ring or opening located at each end.

This shock-absorbing means of attachment or shock-absorbing complement for a means of attachment can be produced in several sizes corresponding to the various standard or non-standard fastening part dimensions.

These modes of production can be combined, the flexible part located between the ends remaining an invariable characteristic.

The appended drawings illustrate the invention:

FIG. 1 shows in perspective a version comprising between its ends (EX) a flexible part (PS) which has the shape of a cylinder open along its length and at each end (EX) an opening (O) perpendicular to the cylinder open along its length.

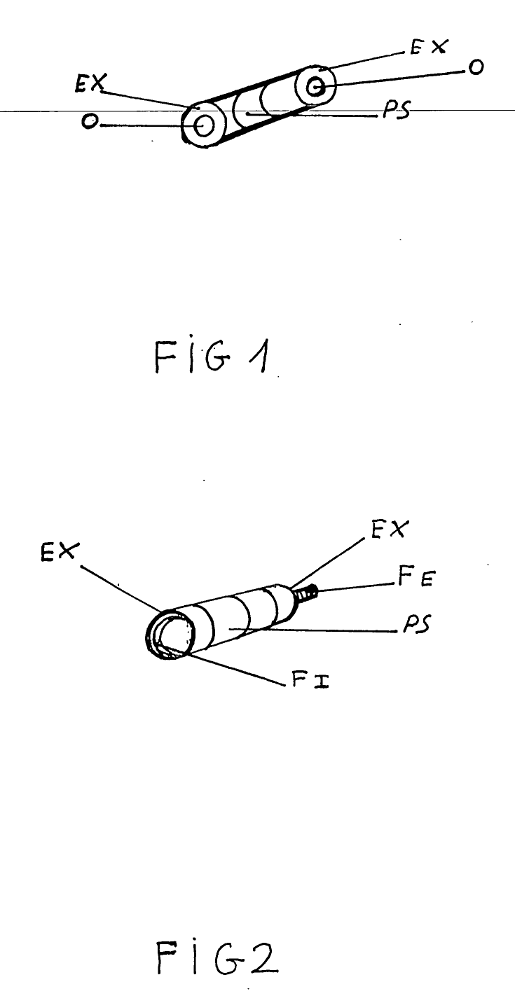

FIG. 2 shows in perspective a version comprising between its ends (EX) a flexible part (PS) which has the shape of a cylinder and comprising at one end (EX) an external thread (FE) and at the other end (EX) an internal thread (FI).

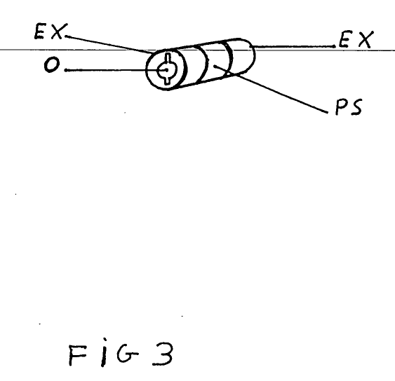

FIG. 3 shows in perspective a version comprising between its ends (EX) a flexible part (PS) which has the shape of a cylinder and comprising on opening (O) at each end (EX) enlarged by two slots each located on either side of this opening (O).

### REVENDICATION

1) Moyen de fixation amortisseur pour composants et carte support de circuit imprimé et de composants caractérisé en ce qu'il comporte au moins deux extrémités (EX) dont chacune d'elles est pourvue d'un orifice (O) et/ou d'un filetage intérieur ou extérieur (FI, FE) et caractérisé en ce que la ou les parties situées entre ces deux extrémités (EX) constituent une partie souple (PS) permettant aux deux extrémités (EX) d'eêtre mobiles l'une par rapport à l'autre une fois le moyen de fixation selon la présente invention installé en situation de fixation entre deux objets distincts.

1) Shock-absorbing means of attachment for components and printed circuit and component support board, charaterised by the fact that it has a flexible part (PS) between its ends (EX).

2) Shock-absorbing means of attachment for components and printed circuit and component support board in accordance with claim 1, characterised by the fact that it has an opening (O) at at least one of its ends (EX).

3) Shock-absorbing means of attachment for components and printed circuit and component support board in accordance with claim 1 or claim 2, characterised by the fact that it has an external thread (FE) at at least one of its ends (EX).

4) Shock-absorbing means of attachment for components and printed circuit and component support board in accordance with any one of the previous claims, characterised by the fact that it has an internal thread (FI) at at least one of its ends (EX).
